(19) United States
(12) Patent Application Publication
(10) Pub. No.: US 2026/0290764 A1
(43) Pub. Date: Sep. 24, 2026

(54) BACKUP ABATEMENT REACTOR FOR A PROCESSING TOOL

(71) Applicant: Applied Materials, Inc., Santa Clara, CA (US)

(72) Inventors: Ju Hyung LEE, Santa Clara, CA (US); Sushim KOSHTI, Portland, OR (US); Venugopal VELLANKI, Santa Clara, CA (US)

(21) Appl. No.: 19/571,362

(22) Filed: Mar. 18, 2026

Related U.S. Application Data
(60) Provisional application No. 63/774,275, filed on Mar. 19, 2025.

(51) Int. Cl. H01J 37/32

(52) U.S. Cl. CPC H01J 37/32844; H01J 37/32449; H01J 2237/022

(57) ABSTRACT

Aspects generally relate to methods and systems for deploying one or more backup abatement reactors for processing chambers to enhance system reliability. The system includes a first processing chamber coupled by a first pre-reactor foreline to a first pre-pump plasma abatement reactor, the first pre-pump plasma abatement reactor coupled by a first post-reactor foreline to a first pump and a backup pre-pump plasma abatement reactor selectively coupling the first processing chamber to the first pump in a manner that prevents gases from being abated by the first pre-pump plasma abatement reactor. One or more first valves are included that have states that control through which of the first pre-pump plasma abatement and the backup pre-pump plasma abatement reactor the first processing chamber is connected to the first pump

### CROSS-REFERENCE TO RELATED APPLICATIONS

This application claims benefit of United States provisional patent application Ser. No. 63/774,275, filed Mar. 19, 2025, which is herein incorporated by reference in its entirety.

### BACKGROUND

### Field

Aspects generally relate to deploying one or more secondary or backup or complementary abatement reactors for processing chambers of a processing tool to enhance system reliability.

### Description of the Related Art

Pre-pump plasma abatement systems are beneficial in mitigating the environmental impact of industrial processes that generate harmful greenhouse gases and volatile organic compounds (VOCs). These systems utilize plasma technology to break down hazardous gases, such as perfluorocarbons (PFCs), into less harmful byproducts, reducing their contribution to greenhouse gas emissions. Widely employed in semiconductor manufacturing, chemical processing, and other industries, pre-pump plasma abatement aids in meeting environmental regulations and sustainability goals.

In traditional setups, a single pre-pump abatement system is dedicated to each processing chamber, creating a one-to-one dependency between the chamber and its pre-pump abatement unit. This architecture means that if the pre-pump abatement system experiences a failure, such as a mechanical fault, gas supply issue, or control malfunction, the corresponding processing chamber is forced to shut down as well, since it can no longer handle or neutralize hazardous byproducts. This direct coupling not only limits operational flexibility but also impacts overall manufacturing throughput and efficiency, as the failure of a single pre-pump abatement system effectively halts the operation of the corresponding chamber.

### SUMMARY

Aspects generally relate to deploying one or more secondary or backup or complementary abatement reactors for processing chambers of a processing tool to enhance system reliability.

In one implementation, a system includes a first processing chamber coupled by a first pre-reactor foreline to a first pre-pump plasma abatement reactor, the first pre-pump plasma abatement reactor coupled by a first post-reactor foreline to a first pump and a backup pre-pump plasma abatement reactor selectively coupling the first processing chamber to the first pump in a manner that prevents gases from being abated by the first pre-pump plasma abatement reactor.

In one implementation, a system includes a first pre-pump plasma abatement reactor coupled to a first processing chamber, a first pump coupled to the first pre-pump plasma abatement reactor, and a post-pump plasma abatement reactor coupled to the first pump and configured to prevent gases from being abated by the first pre-pump plasma abatement reactor.

In one implementation, a method includes coupling, by a first pre-reactor foreline, a first processing chamber to a first pre-pump plasma abatement reactor, the first pre-pump plasma abatement reactor coupled by a first post-reactor foreline to a first pump and selectively coupling, by a backup pre-pump plasma abatement reactor, the first processing chamber to the first pump in a manner that prevents gases from being abated by the first pre-pump plasma abatement reactor.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 illustrates a primary pre-pump plasma abatement reactor including a backup or secondary pre-pump plasma abatement reactor coupled to a processing chamber before the pumps, according to one implementation.

FIG. 2 illustrates a primary pre-pump plasma abatement reactor including a backup or secondary post-pump plasma abatement reactor coupled to a processing chamber after the pumps and without diverters, according to one implementation.

FIG. 3 illustrates a primary pre-pump plasma abatement reactor including a backup or secondary post-pump plasma abatement reactor coupled to a processing chamber after the pumps and with diverters, according to one implementation.

FIG. 4 is a flowchart of a method for coupling a backup or secondary pre-pump plasma abatement reactor to a processing chamber before the pumps, according to one implementation.

FIG. 5 is a flowchart of a method for coupling a backup or secondary post-pump plasma abatement reactor (e.g., a burn-wet abatement system or a plasma-wet abatement system or other type of abatement system) to a processing chamber after the pumps, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Aspects generally relate to deploying one or more secondary or backup or complementary abatement reactors for processing chambers of a processing tool to enhance system reliability.

A pre-pump abatement system or reactor safely and efficiently treats hazardous byproducts generated during semiconductor manufacturing processes. Utilizing advanced plasma technology, the pre-pump abatement system effectively neutralizes hazardous and corrosive gases, converting them into benign compounds such as water vapor and carbon dioxide. This approach not only ensures compliance with stringent environmental regulations but also enhances operational safety by mitigating risks associated with untreated exhaust gases.

At the core of plasma pre-pump abatement system is its pre-pump reactor, which employs high-energy plasma to dissociate and recombine molecular bonds of harmful byproducts. This process is effective for treating a wide range of chemical emissions, including perfluorinated compounds (PFCs), volatile organic compounds (VOCs), and reactive gases like fluorine (F₂) and hydrogen chloride (HCl). The pre-pump abatement system's modular design allows it to adapt to diverse chamber configurations and varying process loads, making it suitable for a broad spectrum of semiconductor applications.

The pre-pump abatement system integrates seamlessly with modern semiconductor manufacturing tools. The pre-pump abatement system supports dynamic flow adjustment and real-time monitoring, enabling precise control of pre-pump abatement processes based on the specific emission profile of the connected chambers. This adaptability not only optimizes performance but also reduces energy consumption and reagent usage, aligning with sustainability goals. Additionally, its compact footprint and centralized control capabilities make it an ideal choice for fabs determined to maximize space efficiency while maintaining high operational reliability.

The pre-pump abatement system further incorporates diagnostics and predictive maintenance features, allowing operators to identify potential issues before they lead to system failures. Automated alerts and self-cleaning mechanisms further enhance system longevity and reduce maintenance downtime. These features ensure consistent performance even in high-demand production environments. As such, the pre-pump abatement system offers a powerful combination of efficiency, adaptability, and environmental compliance. By effectively neutralizing hazardous byproducts and seamlessly integrating with modern semiconductor tools, the pre-pump abatement system enables fabs to achieve high production throughput while meeting environmental and safety standards.

Traditionally, a single pre-pump plasma abatement reactor is dedicated to each processing chamber, providing gas treatment for the chamber's emissions. However, when a pre-pump plasma abatement reactor experiences a failure or needs maintenance, the corresponding processing chamber is taken offline, leading to operational downtime, reduced productivity, and potential disruptions to manufacturing schedules. To address this challenge, a new approach presented by the example embodiments involves deploying one or more secondary or backup or complementary pre-pump or post-pump abatement reactors, introducing redundancy and significantly enhancing system reliability.

Under the proposed system architecture, in one example, a backup or secondary pre-pump abatement reactor is employed before the pumps. A backup pre-pump abatement reactor may be coupled to each pre-reactor foreline of multiple processing chambers. Alternatively, a single backup pre-pump abatement reactor may be coupled to the pre-reactor forelines of each of the multiple processing chambers. The backup pre-pump abatement reactor ensures that when the primary system is offline, the backup pre-pump abatement reactor can immediately take over, minimizing downtime and preventing emissions from circumventing treatment. In another example, a backup or secondary abatement reactor is employed after the pumps. A pre-pump abatement reactor can be employed before the pumps and a post-pump abatement reactor/system can be employed after the pumps (e.g., a burn-wet abatement system or a plasma-wet abatement system or other type of abatement system). The pre-pump abatement reactor placed before the pumps may work in a complimentary manner with the post-pump abatement reactor/system placed after the pumps. Having a backup or complementary post-pump abatement reactor/system ensures that exhaust gases are processed through an alternative method when the pre-pump abatement reactor is offline or during periods when plasma treatment is less efficient. In one example, diverters are used to divert the gases directly to the wet section (bypassing the burn/hot section).

Backup or secondary or complementary abatement reactors use control systems to enable seamless failover without end user involvement. In the event of a failure in the primary pre-pump abatement reactor, the backup or secondary or complementary system is immediately activated, minimizing any disruption to the processing chamber's operations. Monitoring mechanisms continuously assess the health of each reactor system, providing early warnings of potential issues and triggering the transition process when needed. This approach not only enhances reliability but also prevents the release of untreated emissions, safeguarding environmental compliance.

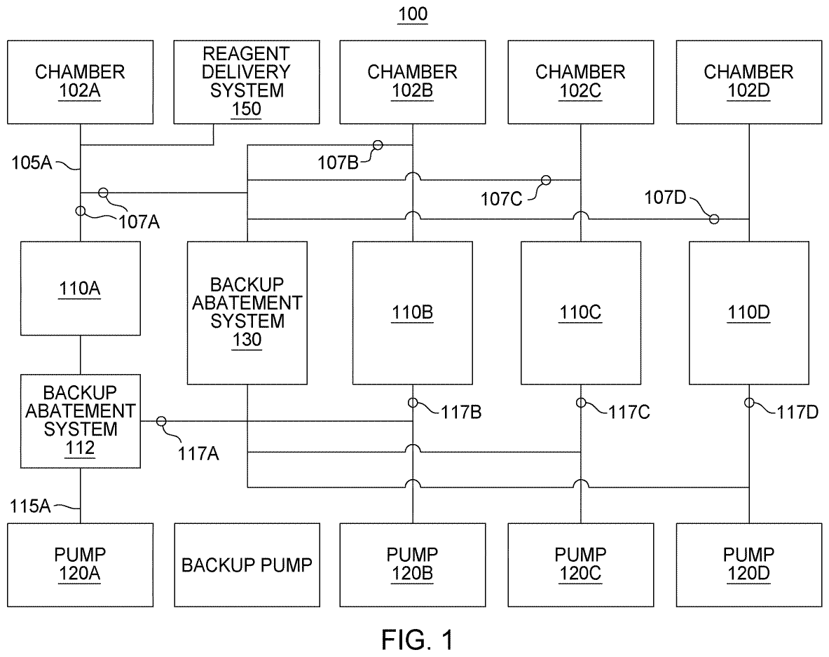

FIG. 1 illustrates a primary plasma pre-pump abatement reactor including a backup or secondary pre-pump plasma abatement reactor coupled to a processing chamber before the pumps, according to one implementation.

The system 100 shows multiple chambers coupled to multiple pumps via respective pre-pump abatement systems or reactors. The terms pre-pump abatement system and pre-pump abatement reactor may be used interchangeably. In one example, a first chamber 102A is coupled to a first pre-pump plasma abatement reactor 110A via a first pre-reactor foreline 105A. The first pre-pump plasma abatement reactor 110A is coupled to a first pump 120A. A second chamber 102B is coupled to a second pre-pump plasma abatement reactor 110B via a second pre-reactor foreline 105B. The second pre-pump plasma abatement reactor 110B is coupled to a second pump 120B. A third chamber 102C is coupled to a third pre-pump plasma abatement reactor 110C via a third pre-reactor foreline 105C. The third pre-pump plasma abatement reactor 110C is coupled to a third pump 120C. A fourth chamber 102D is coupled to a fourth pre-pump plasma abatement reactor 110D via a fourth pre-reactor foreline 105D. The fourth pre-pump plasma abatement reactor 110D is coupled to a fourth pump 120D.

A reagent delivery system 150 is coupled to the first pre-reactor foreline 105A between one or more valves and the first chamber 102A. The reagent delivery system 150 supplies and controls the flow of reagent gases used for the plasma pre-pump abatement process. The reagent delivery system 150 reduces or neutralizes hazardous emissions by converting hazardous substances into safer byproducts.

Isolation valves or ISO valves may be employed on the pre-reactor forelines of the multiple chambers and on connection points between chambers. The first chamber 102A may include isolation valves 107A, the second chamber 102B may include isolation valves 107B, the third chamber 102C may include isolation valves 107C, and the fourth chamber 102D may include isolation valves 107D. The ISO valves help direct flow to the backup abatement system when the primary pre-pump abatement system is down. As such, the ISO valves are used to direct flow either to the primary or the backup abatement reactors.

The system 100 may be a processing tool. A processing tool performs specific tasks in the semiconductor manufacturing process. A processing tool is a multi-functional unit that integrates chambers, controllers, and subsystems to carry out operations, such as deposition, etching, oxidation, or ion implantation. A processing tool may include multiple processing chambers, a centralized control system, gas delivery systems, pre-pump abatement systems/reactors, load-lock chambers, and other supporting hardware and software. A processing tool ensures that substrates are moved between chambers in the correct sequence, environmental conditions are tightly controlled, and processes are optimized for high throughput and precision.

A processing chamber (e.g., the first chamber 102A) is an area within the processing tool where individual steps of the semiconductor manufacturing process occur. Each chamber may handle a specific operation, such as deposition, etching, or plasma treatment. A processing chamber includes substrate handling mechanisms, gas inlets, vacuum pumps, temperature control systems, and reaction zones. A processing chamber isolates the substrate from contamination and ensures that process parameters like pressure, temperature, and gas composition are maintained accurately.

A pump (e.g., the first pump 120A) maintains the vacuum conditions within the processing chamber and manages flow of gases and byproducts out of the processing chamber. The pump ensures that the pressure inside the processing chamber remains stable and suitable for processes, such as deposition, etching, or cleaning. The pump also helps evacuate reaction byproducts and unreacted gases, preventing contamination in the processing chamber.

In a first configuration, in a processing tool where each processing chamber is equipped with its own dedicated backup pre-pump abatement reactor, such approach emphasizes maximum reliability and operational continuity. This approach ensures that every processing chamber has both a primary and a backup pre-pump abatement unit directly coupled to its foreline, providing a localized fail-safe mechanism. If the primary pre-pump abatement reactor for a chamber fails, the backup pre-pump abatement reactor immediately takes over without any disruption to the chamber's operations. This eliminates the need for cross-routing exhausts between chambers and reduces the complexity of shared backup systems, offering an isolated, chamber-specific safety net.

In one example, a backup pre-pump abatement reactor 112 is shown coupled to the first pre-pump plasma abatement reactor 110A (which may be the primary pre-pump abatement reactor for the first chamber 102A). The first pre-pump plasma abatement reactor 110A is coupled in series to the backup pre-pump abatement reactor 112. Similarly, a backup or secondary pre-pump abatement reactor may be coupled to each of the primary pre-pump abatement reactors of each of the chambers. As such, each chamber may be coupled to a primary and a backup pre-pump abatement reactor (not shown). The backup pre-pump abatement reactor of each chamber may employ isolation valves to manage the flow of exhaust gases. In one example, the backup pre-pump abatement reactor 112 for the first chamber 102A may employ a valve 117A, the backup pre-pump abatement reactor for the second chamber 102B may employ a valve 117B, the backup pre-pump abatement reactor for the third chamber 102C may employ a valve 117C, and the backup pre-pump abatement reactor for the fourth chamber 102D may employ a valve 117D.

The advantage of this configuration (i.e., primary pre-pump abatement reactor and secondary pre-pump abatement reactor coupled in series for each chamber) is the reliability it provides to each chamber. By having a dedicated backup pre-pump abatement reactor (i.e., a one-to-one coupling of backup pre-pump abatement systems/reactors and chambers), any issues with the primary pre-pump abatement reactor are contained and managed at the chamber level. This localized redundancy ensures that failures do not propagate across the system, allowing other chambers and processes to continue unaffected. For semiconductor manufacturing processes involving high uptime and minimal risk of contamination, such an approach offers robust operational security.

However, this architecture comes with drawbacks, primarily in terms of cost and spatial efficiency. Implementing a backup pre-pump abatement reactor for each chamber involves double the investment in abatement equipment. The increased hardware not only increases expenditures but also adds to ongoing operational costs, such as energy consumption, maintenance, and spare parts. This makes such approach less viable for cost-conscious fabs or those operating under tight budget constraints.

Additionally, the spatial footprint of this setup may be a disadvantage, particularly in modern fabs where subfab space is limited. Backup pre-pump abatement reactors for every chamber involves more floor space and infrastructure for installation and operation. This can complicate tool layouts, increase construction and utility costs, and limit the ability to add other equipment in the subfab. For fabs with a high density of chambers, the sheer volume of hardware can create logistical challenges, reducing overall efficiency.

Therefore, while providing reliability and chamber-specific redundancy, a processing tool with dedicated backup or secondary pre-pump abatement reactors for each chamber may be expensive to implement and takes up considerable space. These disadvantages may outweigh the benefits for certain fabs, especially those prioritizing cost-effectiveness and space optimization. However, for fabs that prioritize reliability above all and can accommodate the financial and spatial demands, this architecture ensures the highest level of fault tolerance and operational independence for each processing chamber.

In a second configuration, incorporating a backup pre-pump abatement reactor 130 coupled to the foreline of each of the processing chambers in a semiconductor tool represents an enhancement in operational resilience, efficiency, and safety. This approach moves away from the one-to-one coupling of backup pre-pump abatement reactors and chambers, providing a fail-safe mechanism for uninterrupted production. By connecting a single, shared backup pre-pump abatement reactor to the foreline of each of the chambers, the risk of downtime due to pre-pump abatement reactor failure is significantly reduced, as the backup pre-pump abatement reactor 130 can seamlessly take over when any primary pre-pump abatement reactor encounters an issue or failure or maintenance downtime.

In one example, the backup pre-pump abatement reactor 130 is a single secondary system that couples each of the chambers. The backup pre-pump abatement reactor 130 is positioned before the pumps of the system 100. As such, each system 100 or processing tool may include one secondary or backup pre-pump abatement reactor. The backup pre-pump abatement reactor 130 can also be referred to as a backup pre-pump plasma abatement reactor. The backup pre-pump plasma abatement reactor selectively couples, e.g., the first chamber 102A to the first pump 120A in a manner that prevents the gases from being abated by the first pre-pump plasma abatement reactor 110A.

This approach may include a dynamic switching mechanism that monitors the operational status of every pre-pump abatement reactor in real time. The system 100 continuously checks for performance anomalies or failures in the primary pre-pump abatement reactors serving individual chambers. If an issue is detected, the switching mechanism reroutes the foreline exhaust to the backup pre-pump abatement reactor without interrupting the ongoing process in the chamber. This transition is automated and occurs with minimal latency, ensuring that hazardous emissions are consistently treated and production continues smoothly.

This single, shared backup pre-pump abatement reactor also brings substantial cost and space efficiency benefits. Instead of dedicating a full backup unit to each processing chamber, a single backup pre-pump abatement reactor serves multiple chambers, reducing expenditure and limiting the physical footprint in the subfab. This configuration is advantageous in fabs where space is at a premium and operational budgets are tightly controlled. Additionally, fewer backup pre-pump abatement reactors means reduced energy consumption and maintenance requirements, contributing to lower operational expenses and improved sustainability.

Another advantage of this approach is enhanced operational flexibility. The backup pre-pump abatement reactor 130 can support multiple chamber types with varying emission profiles, allowing the backup pre-pump abatement reactor 130 to adapt to different processes. This flexibility is beneficial for fabs handling diverse manufacturing workflows, such as etching, deposition, and cleaning, where emission byproducts can vary significantly in composition and volume. The backup pre-pump abatement reactor 130 ensures that even in the event of a primary pre-pump abatement failure, the process-specific abatement requirements are still met.

The integration of the backup pre-pump abatement reactor 130 also strengthens compliance with environmental regulations. Semiconductor manufacturing processes generate emissions that are highly regulated due to their potential impact on the environment and worker safety. The backup pre-pump abatement reactor 130 ensures continuous abatement of harmful byproducts, preventing unfiltered emissions during equipment downtime.

Moreover, the primary and secondary pre-pump abatement reactors are positioned before the pumps to treat process gases and byproducts before they pass through the vacuum pump. By treating hazardous gases before they enter the pump components, the pre-pump abatement reactors minimize exposure of the pump components to potentially damaging byproducts.

Therefore, in the two approaches of FIG. 1, the pre-pump abatement process and switching between pre-pump abatement reactors occurs before the pumps. This can be referred to as a pre-pump approach. Thus, in this approach, the primary and backup pre-pump abatement reactors are positioned upstream of the pumps.

In summary, coupling the backup pre-pump abatement reactor 130 to the pre-reactor foreline of each of the processing chambers in a tool or system 100 increases uptime, optimizes costs, and maintains environmental compliance. By providing a shared fail-safe mechanism, this approach minimizes production interruptions, improves resource efficiency, and ensures a safer working environment. The benefits of having a backup pre-pump abatement reactor include elimination of downtime, increased operational reliability, scalability for expanding operations, and enhanced environmental compliance.

With backup pre-pump abatement systems/reactors, a single failure no longer necessitates halting every connected chamber. Instead, chambers continue operating seamlessly, with emissions being routed to one or more functional pre-pump abatement units. This approach reduces downtime, preserving production schedules and avoiding costly disruptions.

Backup pre-pump abatement reactors enhance reliability by distributing the workload and ensuring failover capabilities. Advanced monitoring tools can detect early signs of failure in a pre-pump abatement reactor, triggering the backup or secondary pre-pump abatement reactor before a complete breakdown occurs.

Manufacturing facilities often need to scale production over time. A backup pre-pump abatement setup can accommodate additional chambers or increased emissions without overloading a single system. As new chambers are added, corresponding abatement capacity can be incorporated into the network.

Continuous operation of pre-pump abatement systems/reactors ensures consistent treatment of harmful emissions, even during maintenance or failure events. This uninterrupted compliance with environmental standards reduces the risk of regulatory penalties and reinforces the manufacturer's commitment to sustainability.

In one example, redundancy can be implemented in two configurations, an active-active configuration and an active-passive configuration. In an active-active configuration, every pre-pump abatement reactor operates simultaneously, sharing the load. If one pre-pump abatement reactor fails, the remaining one or more pre-pump abatement reactors automatically take over its workload. In an active-passive configuration, one system operates as the primary unit, while a secondary unit remains on standby and activates only when the primary system fails. The examples may implement either configuration.

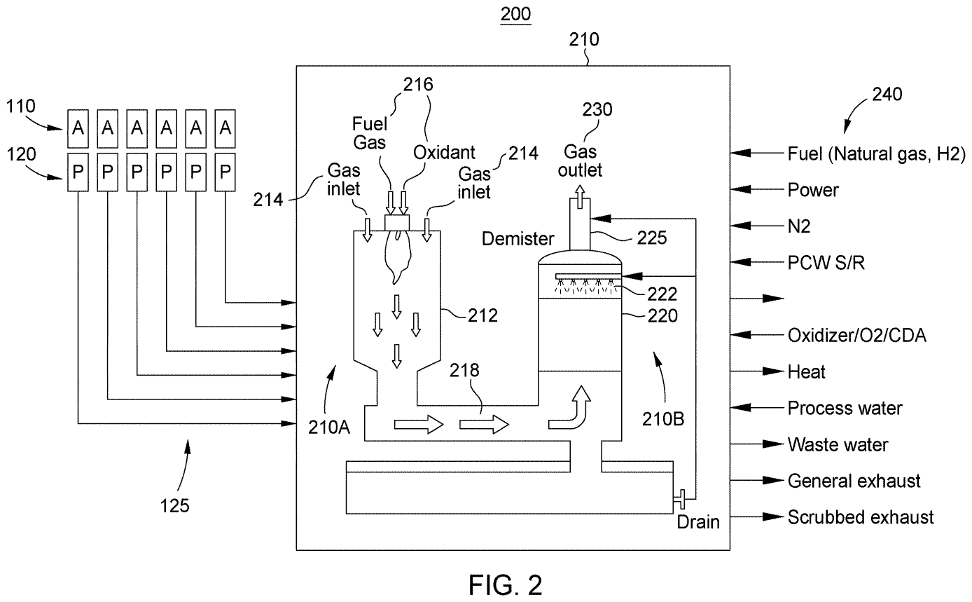

FIG. 2 illustrates a primary pre-pump plasma abatement reactor including a backup or secondary post-pump plasma abatement reactor coupled to a processing chamber after the pumps and without diverters, according to one implementation.

In the two approaches of FIG. 1, the abatement process and switching between pre-pump abatement systems/reactors occurs before the pumps. This can be referred to as a pre-pump approach. In contrast, in the approach of FIG. 2, the abatement process and switching between abatement reactors occurs after the pumps. This can be referred to as a post-pump approach. In this approach, the backup post-pump abatement reactors are located downstream of the pumps. These systems treat gases after they have been compressed and partially diluted by the pumps.

In the system 200 the pre-pump plasma abatement reactors 110 are coupled to respective pumps 120. The outlets 125 of the pumps 120 are connected to a post-pump abatement reactor 210. The post-pump abatement reactor 210 can include a burn-wet (BW) abatement system or a plasma-wet (PW) abatement system or other type of abatement system. In one non-limiting example, the post-pump abatement reactor 210 includes a burn section 210A and a wet section 210B.

In the burn section 210A, combustible gases and vapors are oxidized at high temperatures in a controlled environment. This process converts hazardous compounds into less harmful substances, such as carbon dioxide (CO₂), water vapor, or other benign gases. The burn section 210A includes gas inlets 214 for receiving fuel gas and oxidants 216 into a burn chamber 212. After combustion, the gas stream 218 passes through a wet scrubber 220, where water or neutralizing solution 222 captures and removes acid gases, particulates, and other byproducts. This is referred to as the wet section 210B. The wet scrubber 220 neutralizes compounds such as hydrogen fluoride (HF) or hydrogen chloride (HCl), and other acidic or corrosive byproducts generated during the burn process. This involves sprays or contact with a liquid medium (via a demister 225) to dissolve or chemically neutralize pollutants. The wet scrubber 220 may also include a gas outlet 230 to output treated gas and liquid waste. The demister 225 is located near the gas outlet 230 to remove the entrained water droplets from the treated gas stream.

The post-pump abatement reactor 210 combines thermal oxidation (the burn section 210A) and wet scrubbing processes (the wet section 210B) to treat hazardous gases and byproducts. The system has several inputs and outputs, collectively referred to as elements 240. Elements entering the post-pump abatement reactor 210 may include, e.g., process gases, natural gas or fuel, nitrogen (N₂), and process water. Process gases may include hazardous gases and byproducts. Natural gas or fuel may be used as a combustible fuel for the heat oxidizer in the burn section 210A. The natural gas ensures sufficient energy to maintain the high temperatures needed for thermal oxidation of the process gases. N₂ acts as a purge gas or inert gas to prevent unwanted chemical reactions. The process water is supplied to the wet section 210B as the scrubbing medium. Elements exiting the post-pump abatement reactor 210 may include, e.g., exhaust gas, waste water, and heat energy. The exhaust gas is mainly CO₂, water vapor, and other benign byproducts.

In the system 200, the abatement process and switching between abatement reactors occurs after the pumps, which is referred to as a post-pump approach.

When the pre-pump plasma abatement reactor (e.g., one of the pre-pump plasma abatement reactors 110) located before the pump (e.g., one of respective pumps 120) is activated, its function is to break down hazardous gases and byproducts at their source. This reduces the load on downstream post-pump abatement systems/reactors by minimizing the concentration of harmful compounds such as PFCs and VOCs. The plasma chamber operates by ionizing the exhaust gases using high-energy plasma, which disintegrates complex molecules into simpler, less toxic components.

With the pre-pump plasma abatement reactor handling the primary neutralization, the burn section 210A of the post-pump abatement reactor 210 downstream can be turned off or set to a low/idle mode. The wet section 210B is then activated to scrub any residual acids or water-soluble byproducts effectively. The wet section 210B employs a liquid-based scrubbing process, using water or an alkaline solution, to absorb and neutralize acidic compounds such as hydrogen fluoride (HF) or sulfur dioxide (SO₂).

During operation, the exhaust from the pre-pump plasma abatement reactor flows directly to the wet section 210B without passing through the burn section 210A. The wet scrubber's pumps and fluid circulation systems are optimized to maintain constant flow rates and ensure thorough mixing of the exhaust with the scrubbing liquid. Any precipitates formed during this process are collected in sedimentation tanks or filtration units, allowing the cleaned exhaust gases to be safely vented to the atmosphere. A system controller dynamically coordinates this flow based on the load handled by the upstream pre-pump plasma abatement reactor.

This operational strategy provides multiple advantages. Firstly, turning off the burn section 210A (or setting it to a low/idle mode) reduces energy consumption and wear on high-temperature components, extending their lifespan. Secondly, using the wet section 210B to scrub acids ensures effective removal of water-soluble compounds, leading to cleaner exhaust. Additionally, the reduction in thermal energy requirements results in lower greenhouse gas emissions, supporting environmental sustainability goals. Finally, this configuration offers operational flexibility, enabling the system to adapt dynamically to varying exhaust compositions and flow rates.

When the pre-pump plasma abatement reactor (e.g., one of the pre-pump plasma abatement reactors 110) before the pump (e.g., one of respective pumps 120) is turned off, typically due to chamber downtime or maintenance, there is a need for a backup system to handle the exhaust gases and maintain safe emissions levels. In this case, the burn section 210A of the post-pump abatement reactor 210, located downstream of the pumps 120, is activated to ensure that the abatement process continues uninterrupted. The burn section 210A serves as a high-temperature incinerator that can break down complex gases, such as PFCs and VOCs, into simpler, less harmful substances like CO₂ and water.

The transition to using the burn section 210A during the plasma system's downtime is designed for seamless operation. Once the pre-pump plasma abatement reactor is offline, the exhaust gases are directed (e.g., the outlets 125) to the burn section 210A. The gases are subjected to high temperatures in a combustion chamber, where they are oxidized or thermally decomposed. This process ensures that even if the plasma system isn't operational, harmful byproducts like HF, carbon tetrafluoride (CF₄), and other fluorinated gases are effectively neutralized, meeting regulatory and safety standards for exhaust emissions.

The flow of exhaust gases in this backup scenario is managed by the system's controller, which dynamically adjusts the operation based on the status of the pre-pump plasma abatement reactor. When the pre-pump plasma abatement reactor is active, gases are directed to the wet section, but during downtime, the exhaust is rerouted to the burn section 210A. The controller also ensures the burn section 210A maintains the appropriate temperature and gas flow to optimize the combustion process. After passing through the burn section 210A, the exhaust gases move to the wet section 210B of the post-pump abatement reactor 210 for further neutralization and to remove any remaining acidic compounds or particulates.

This backup configuration enhances system reliability and ensures that there is no downtime in emissions control, even during the maintenance or failure of the pre-pump plasma abatement reactor 110 before the pumps 120. The burn section 210A can be relied upon as a failsafe mechanism to handle exhaust gases without compromising the overall performance of the system. Furthermore, the post-pump abatement reactor's redundancy is beneficial for maintaining operational continuity and meeting regulatory compliance, as facilities are often need to show that they can manage emissions continuously, regardless of system downtime.

While the burn section 210A consumes more energy due to its high-temperature requirements, it is a cost-effective solution in the long run as it prevents operational disruptions and ensures emissions are within acceptable limits. Moreover, this redundancy prevents overreliance on the pre-pump plasma abatement reactor 110, allowing for better load distribution across the system 200. The system 200 is more sustainable, as it reduces the risk of operational halts and ensures a continuous, safe process, aligning with both environmental and business goals.

In other examples, the burn section 210A of the post-pump abatement reactor 210 is not just a backup, but a complementary system. In this configuration, the pre-pump plasma abatement reactor and the post-pump abatement reactor after the pump can operate in parallel or in tandem or simultaneously. The pre-pump plasma abatement reactor may be optimized to break down high-concentration gases like PFCs, whereas the burn section 210A of the post-pump abatement reactor 210 can handle complex, high-temperature byproducts that may be harder to treat with plasma alone. The operation can be coordinated by a system controller, which can manage the exhaust flow to ensure optimal treatment across both pre-pump and post-pump abatement reactors. When the pre-pump plasma abatement reactor is off, the gases are diverted to the burn section of the post-pump abatement reactor, where they are exposed to high temperatures, facilitating oxidation and thermal decomposition of harmful compounds. As the burn section neutralizes the volatile gases, the exhaust flows into the wet section, which further scrubs out any residual acids. This complementary approach ensures that the exhaust is fully neutralized without relying solely on the pre-pump plasma abatement reactor. Thus, by using both pre-pump and post-pump abatement reactors, to complement one another, the system 200 can treat a broader range of exhaust compositions more efficiently. The burn section 210A adds an extra layer of flexibility, allowing for more complex or fluctuating gas profiles to be handled without causing strain on the pre-pump plasma abatement reactor. This complementary system allows for better load management, reduces the risk of downtime emissions control, and offers operational flexibility to maintain lower energy consumption and lower operational costs.

In one example, to maximize the effectiveness of the burn section 210A as a complementary system, operational parameters may be adjusted. That is, the burner temperature, airflow rates, and fuel supply may need to be adjusted or fine-tuned to obtain optimal combustion conditions. For example, if the exhaust includes a higher concentration of PFCs, or other refractory gases, the burner temperature may need to be increased to achieve proper decomposition. The switching between the pre-pump plasma abatement reactor and the post-pump abatement reactor can be based on gases found in the processing chamber. For example, in one cycle, the chamber may emit fluorinated compounds that are best treated using pre-pump plasma abatement due to its high-energy decomposition capability. However, in another cycle, the chamber emits a mix of VOCs and acidic byproducts, which are more efficiently neutralized by the post-pump abatement reactor. In such case, the system can switch from the pre-pump plasma abatement reactor to the post-pump abatement reactor, and temperature adjustments can be made in the post-pump abatement reactor to handle the VOCs. This ability to switch abatement reactors based on gas compositions ensures adaptability and robustness in exhaust management. This dual pre-pump, post-pump abatement reactor approach ensures uninterrupted emissions control even when one system is offline, improves treatment efficiency, and reduces energy consumption. As such, each pre-pump and post-pump abatement reactor is used in its optimal operating range. Pre-pump plasma abatement may be ideal for breaking down high-energy compounds, whereas the post-pump abatement reactor may excel in handling acid-forming gases. This complementary approach ensures maximum flexibility and efficiency in handling different gases.

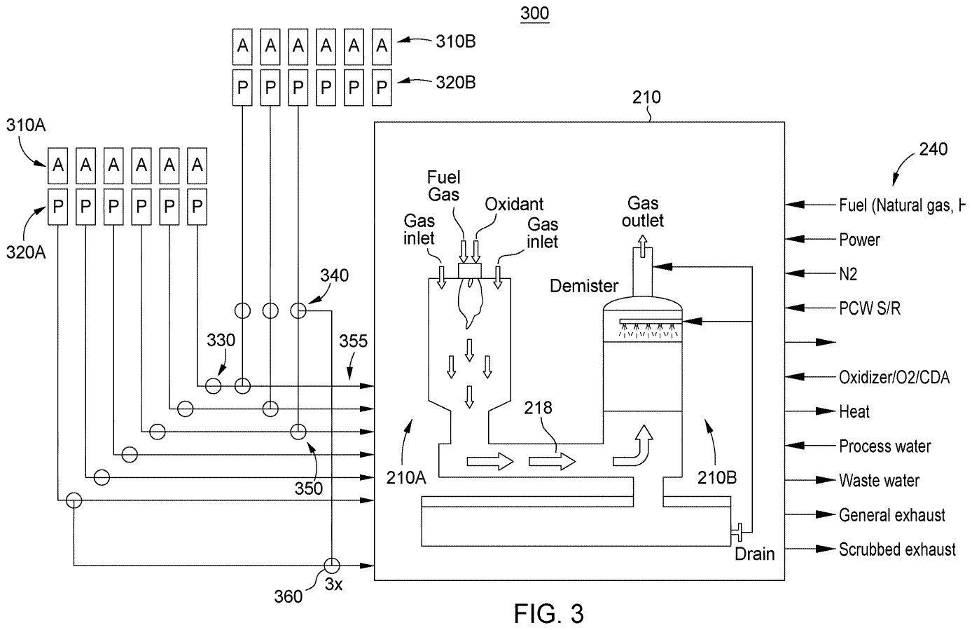

FIG. 3 illustrates a primary pre-pump plasma abatement reactor including a backup or secondary post-pump plasma abatement reactor coupled to a processing chamber after the pumps and with diverters, according to one implementation.

In the system 300, the abatement process and switching between abatement reactors occurs after the pumps, which is referred to as a post-pump approach. This approach is similar to the approach of FIG. 2. However, FIG. 2 does not include diverters, whereas FIG. 3 includes diverters.

In the system 300, a first set of pre-pump plasma abatement reactors 310A are coupled to a first set of pumps 320A and a second set of pre-pump plasma abatement reactors 310B are coupled to a second set of pumps 320B. The first set of pumps 320A are coupled to a first set of valves 330 and the second set of pumps 320B are coupled to a second set of valves 340. The first set of valves 330 and the second set of valves 340 are coupled to first diverters 350 or a second diverter 360 to provide inputs 355 to the post-pump abatement reactor 210.

The first diverters 350 or the second diverter 360 redirect the flow of exhaust gases. In one example, the diverters redirect the flow of gases directly to the wet section (bypassing the burn section). The first diverters 350 or the second diverter 360 are placed after the pumps of the pre-pump plasma abatement reactor and before the post-pump abatement reactor 210 located downstream. When the pre-pump plasma abatement reactor is on (e.g., either a first set of pre-pump plasma abatement reactors 310A or a second set of pre-pump plasma abatement reactors 310B), the diverters direct the exhaust towards the burn/plasma section or directly to the wet section. During plasma downtime, the diverters can reroute the exhaust to the post-pump abatement reactor 210, ensuring continuous treatment without disruption.

The first diverters 350 or the second diverter 360 are controlled by the system's controller, which monitors the operational status of the pre-pump plasma abatement reactor and the exhaust composition. When the pre-pump plasma abatement reactor is operational, the diverters direct the exhaust gases to the burn/plasma section or directly to the wet section, where harmful compounds like PFCs are broken down using high-energy plasma. In the event of plasma downtime, the diverters automatically redirect the exhaust flow to the burn section 210A of the post-pump abatement reactor 210, where high temperatures in the burn section 210A ensure the oxidation of hazardous gases, while the wet section 210B further neutralizes acidic and water-soluble compounds. This dynamic switching ensures that exhaust gases are treated continuously, regardless of the operational status of the plasma system.

Therefore, according to FIGS. 1-3, in some cases, a single backup pre-pump plasma abatement reactor is used when any of the chambers goes offline. The single backup pre-pump plasma abatement reactor is coupled to each of the forelines of the chambers. In other cases, each chamber has its own dedicated backup pre-pump plasma abatement reactor. Each backup pre-pump plasma abatement reactor is coupled in series with a primary pre-pump plasma abatement reactor associated with a respective chamber. In both cases, the single backup pre-pump plasma abatement reactor and the multiple backup pre-pump plasma abatement reactors are placed or positioned or connected before the pumps. In other cases, the pre-pump plasma abatement reactors are coupled directly to pumps, and the pumps are coupled to a backup post-pump plasma abatement reactor. The backup post-pump plasma abatement reactor in this case can be a post-pump abatement reactor that can replace or complement the primary pre-pump plasma abatement reactor. The post-pump abatement reactor is placed or positioned or connected after the pumps. In one example, the post-pump abatement reactor may completely replace the primary pre-pump plasma abatement reactor that went offline. In another example, the post-pump abatement reactor may complement the primary pre-pump plasma abatement reactor to deal with gases that may not be properly handled by the primary pre-pump plasma abatement reactor. As such, the post-pump abatement reactor may work in parallel or in tandem or simultaneously or concurrently with the primary pre-pump plasma abatement reactor. In another case, the primary pre-pump plasma abatement reactor may be deactivated or turned off (e.g., if it is determined that it cannot handle a specific gas), and the post-pump abatement reactor may take over on its own.

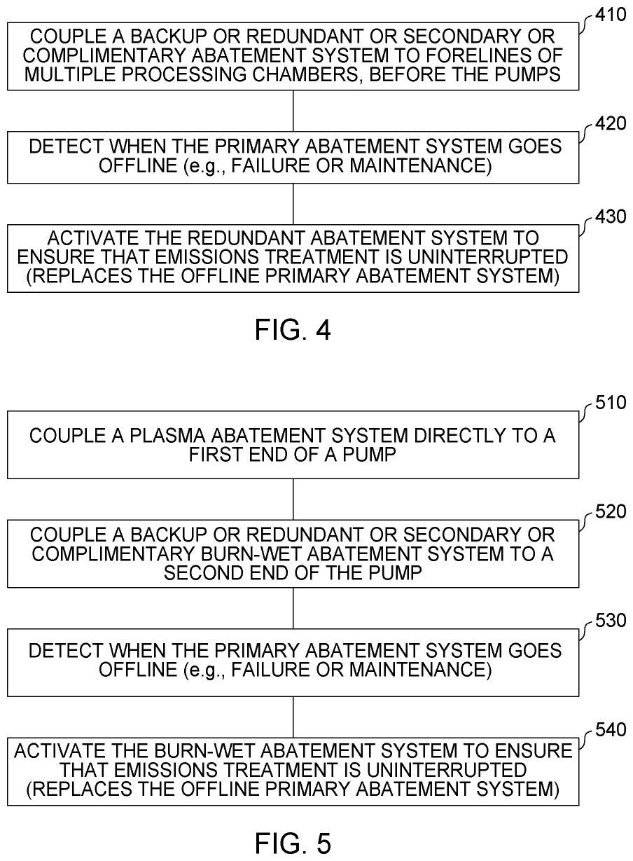

FIG. 4 is a flowchart of a method for coupling a backup or secondary pre-pump plasma abatement reactor to a processing chamber before the pumps, according to one implementation.

At 410, a backup or secondary or complimentary pre-pump abatement reactor is coupled to pre-reactor forelines of multiple processing chambers, before the pumps.

At 420, it is detected when the primary pre-pump plasma abatement reactor goes offline (e.g., failure or maintenance).

At 430, the backup pre-pump abatement reactor is activated to ensure that emissions treatment is uninterrupted.

FIG. 5 is a flowchart of a method for coupling a backup or secondary post-pump plasma abatement reactor (e.g., a burn-wet abatement system or a plasma-wet abatement system or other type of abatement system) to a processing chamber after the pumps, according to one implementation.

At 510, a pre-pump plasma abatement reactor is coupled directly to a first end of a pump.

At 520, a backup or secondary or complimentary post-pump abatement reactor/system is coupled to a second end of the pump.

At 530, it is detected when the primary pre-pump plasma abatement reactor goes offline (e.g., failure or maintenance).

At 540, the post-pump abatement reactor/system is activated to ensure that emissions treatment is uninterrupted. In one example, the post-pump abatement system may be a burn-wet abatement system.

Employing a backup or secondary pre-pump plasma abatement reactor before the pumps provides several benefits in maintaining continuous emissions control. One advantage is system reliability. In environments where pre-pump plasma abatement reactors are used to neutralize harmful gases, any downtime due to maintenance, system failure, or unexpected issues can lead to unprocessed exhaust emissions, potentially violating environmental regulations. A backup pre-pump plasma abatement reactor ensures that when the primary system is offline, the backup system can immediately take over, minimizing downtime and preventing emissions from circumventing treatment. This redundancy guarantees that harmful gases are consistently neutralized, even during system maintenance.

In addition to operational continuity, having a backup pre-pump plasma abatement reactor also increases the flexibility of the overall exhaust management system. The backup system can be used during high-demand periods, such as when the primary system is processing a higher-than-usual exhaust load. This helps balance the treatment capacity and ensures that emissions are processed efficiently, without overwhelming a single system. Moreover, this flexibility allows the plasma system to be tailored to different operating conditions, such as varying exhaust concentrations, ensuring optimal performance under diverse scenarios.

A backup pre-pump plasma abatement reactor enhances load management across the entire emissions control infrastructure. For example, if the primary system is experiencing a lower-efficiency phase due to environmental conditions, the backup system can maintain optimal treatment. Additionally, by utilizing both systems during peak operation, the overall load is distributed, preventing excessive strain on either pre-pump or post-pump abatement reactor. This distribution improves efficiency, reduces the risk of overloading, and helps maintain a stable process, ensuring that the exhaust gases are consistently neutralized at the appropriate levels. Furthermore, by spreading the load across two pre-pump abatement systems/reactors, it extends the service life of each pre-pump and post-pump abatement reactor and lowers the frequency of costly repairs or replacements.

The benefits of employing a backup or secondary post-pump abatement reactor/system after the pumps is also beneficial. The post-pump abatement reactor is well-suited to handle different types of contaminants than a pre-pump plasma abatement reactor, especially those that use high temperatures for decomposition or those that produce acids and particulate matter. Having a backup or complementary post-pump system ensures that exhaust gases are processed through an alternative method when the pre-pump plasma abatement reactor is offline or during periods when pre-pump plasma treatment is less efficient. This versatility makes the post-pump reactor/system an ideal complement to the pre-pump plasma abatement reactor, enhancing the overall flexibility of the emissions control process.

Moreover, a post-pump abatement system is effective at neutralizing acids like HF or SO₂, which are often formed in semiconductor manufacturing. When paired with the pre-pump plasma abatement reactor, the post-pump abatement reactor can handle exhaust gases that may be challenging for the pre-pump plasma abatement reactor to treat, especially those containing high concentrations of particulate matter or complex chemicals. The combination of high-temperature oxidation in the burn section and subsequent scrubbing in the wet section allows for a comprehensive and thorough abatement process, improving the overall exhaust quality.

A complementary post-pump abatement reactor thus ensures continuous and uninterrupted treatment of exhaust gases, even during plasma system downtime or maintenance. This redundancy not only helps in avoiding operational halts but also ensures that no hazardous emissions escape treatment during system transitions. The ability to switch between different abatement methods in real-time maximizes the efficiency of the emissions control process. If one system is temporarily unavailable, the other can immediately take over, ensuring that the exhaust gas is still processed and neutralized, safeguarding compliance with regulatory standards and maintaining a consistent emission profile.

In conclusion, in one example, a backup or secondary pre-pump plasma abatement reactor is employed before the pumps. A backup pre-pump plasma abatement reactor may be coupled to each pre-reactor foreline of multiple processing chambers. Alternatively, a single backup pre-pump plasma abatement reactor may be coupled to the pre-reactor forelines of each of the multiple processing chambers. The backup pre-pump plasma abatement reactor ensures that when the primary system is offline, the backup abatement reactor can immediately take over, minimizing downtime and preventing emissions from circumventing treatment. In another example, a backup or secondary abatement reactor is employed after the pumps. A pre-pump plasma abatement reactor can be employed before the pumps and a post-pump abatement reactor/system can be employed after the pumps. The pre-pump plasma abatement reactor may work in a complimentary manner with the post-pump abatement reactor/system placed after the pumps. Having a backup or secondary post-pump abatement reactor/system ensures that exhaust gases are processed through an alternative method when the pre-pump plasma abatement reactor is offline or during periods when plasma treatment is less efficient. In one example, diverters are used to channel the gases to the post-pump abatement reactor. In another example, the diverters are used to channel the gases directly to the wet section only, bypassing the burn section.

While this specification contains many specific implementation details, these should not be construed as limitations on the scope of what may be claimed, but rather as descriptions of features that may be specific to particular implementations. Certain features that are described in this specification in the context of separate implementations may also be implemented, in combination, in a single implementation. Conversely, various features that are described in the context of a single implementation may also be implemented in multiple implementations, separately, or in any suitable sub-combination. Moreover, although previously described features may be described as acting in certain combinations and even initially claimed as such, one or more features from a claimed combination may, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) may be advantageous and performed as deemed appropriate. While the various steps in an embodiment method or process are presented and described sequentially, one of ordinary skill in the art will appreciate that some or all of the steps may be executed in different order, may be combined, or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Furthermore, any claimed implementation is considered to be applicable to at least a computer-implemented method; a non-transitory, computer-readable medium storing computer-readable instructions to perform the computer-implemented method; and a computer system including a computer memory interoperability coupled with a hardware processor configured to perform the computer-implemented method or the instructions stored on the non-transitory, computer-readable medium.

As used herein, “a CPU”, controller””, “a processor”, “at least one processor”, or “one or more processors”, generally refers to a single processor configured to perform one or multiple operations or multiple processors configured to collectively perform one or more operations. In the case of multiple processors, the one or more operations could be divided amongst different processors, though one processor may perform multiple operations, and multiple processors could collectively perform a single operation. Similarly, “a memory””, at least one memory”, or “one or more memories”, generally refers to a single memory configured to store data and/or instructions, multiple memories configured to collectively store data and/or instructions.

As used herein, “gas” and “fluid” may be used interchangeable with either term generally referring to elements, compounds, materials, etc., having the properties of a gas, a fluid, or both a gas and a fluid.

Unless defined otherwise, all technical and scientific terms used have the same meaning as commonly understood by one of ordinary skill in the art to which these systems, apparatuses, methods, processes and compositions belong.

In this disclosure, the terms “top”, “bottom”, “side”, “above”, “below”, “up”, “down”, “upward”, “downward,” “horizontal,” “vertical,” and the like do not refer to absolute directions. Instead, these terms refer to directions relative to a nonspecific plane of reference. This non-specific plane of reference may be vertical, horizontal, or other angular orientation.

The singular forms “a”, “an”, and “the”, include plural referents, unless the context clearly dictates otherwise. Within a claim, reference to an element in the singular is not intended to mean “one and only one” unless specifically so stated, but rather “one or more”. Unless specifically stated otherwise, the term “some” refers to one or more.

Embodiments of the present disclosure may suitably “comprise”, “consist”, or “consist essentially of”, the limiting features disclosed, and may be practiced in the absence of a limiting feature not disclosed. As used here and in the appended claims, the words “comprise”, “has”, and “include”, and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

“Coupled” and “coupling” means that the subsequently described material is connected to previously described material. The connection may be a direct, or indirect connection, and may, or may not, include intermediary components such as plumbing, wiring, fasteners, mechanical power transmission, electrical communication, wired and/or wireless transmission, etc., which may be suitable to affect operation of the components.

As used, the term “determining” encompasses a wide variety of actions. For example, “determining” may include calculating, computing, processing, deriving, investigating, looking up, for example, looking up in a table, a database, or another data structure, and ascertaining. In addition, “determining” may include receiving, for example, receiving information, and accessing, for example, accessing data in a memory. In addition, “determining” may include resolving, selecting, choosing, and establishing.

When the word “approximately” or “about” are used, this term may mean that there may be a variance in value of up to ±10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values and combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is envisioned under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. It is the express intention of the applicant not to invoke 35 U.S.C. § 112(f), for any limitations of any of the claims, except for those in which the claim expressly uses the words ‘means for’ together with an associated function.

While the foregoing is directed to embodiments of the present disclosure, other and further embodiments of the disclosure may be devised without departing from the basic scope thereof, and the scope thereof is determined by the claims that follow.

What is claimed is:

1. A system, comprising:
a first processing chamber coupled by a first pre-reactor foreline to a first pre-pump plasma abatement reactor, the first pre-pump plasma abatement reactor coupled by a first post-reactor foreline to a first pump; and
a backup pre-pump plasma abatement reactor selectively coupling the first processing chamber to the first pump in a manner that prevents gases from being abated by the first pre-pump plasma abatement reactor.

2. The system of claim 1, further comprising:
a second processing chamber coupled by a second pre-reactor foreline to a second pre-pump plasma abatement reactor, the second pre-pump plasma abatement reactor coupled by a second post-reactor foreline to a second pump, wherein the backup pre-pump plasma abatement reactor is configured to selectively couple the second processing chamber to the second pump in a manner that circumvents the second pre-pump plasma abatement reactor.

3. The system of claim 2, further comprising:
a post-pump abatement system connected to outlets of the first and second pumps.

4. The system of claim 1, further comprising:
one or more first valves having states that control through which of the first pre-pump plasma abatement reactor and the backup pre-pump plasma abatement reactor the first processing chamber is connected to the first pump.

5. The system of claim 4, further comprising:
an abatement reagent delivery system coupled to the first pre-reactor foreline between the one or more first valves and the first processing chamber.

6. The system of claim 1, wherein the backup pre-pump plasma abatement reactor is coupled to the first pre-pump plasma abatement reactor in series.

7. The system of claim 1, wherein the backup pre-pump plasma abatement reactor is coupled to the first pre-pump plasma abatement reactor in parallel.

8. A system, comprising:
a first pre-pump plasma abatement reactor coupled to a first processing chamber;
a first pump coupled to the first pre-pump plasma abatement reactor; and
a post-pump abatement reactor coupled to the first pump and configured to prevent gases from being abated by the first pre-pump plasma abatement reactor.

9. The system of claim 8, further comprising:
a second pre-pump plasma abatement reactor coupled to a second processing chamber; and
a second pump coupled to the second pre-pump plasma abatement reactor, wherein the post-pump abatement reactor is coupled to the second pump and configured to prevent gases from being abated by the second pre-pump plasma abatement reactor.

10. The system of claim 8, further comprising:
one or more first valves having states that control through which of the first pre-pump plasma abatement reactor and the post-pump abatement reactor the first processing chamber is connected to the first pump.

11. The system of claim 10, further comprising:
an abatement reagent delivery system coupled to a first pre-reactor foreline between the one or more first valves and the first processing chamber.

12. The system of claim 10, wherein the post-pump abatement reactor is a burn-wet abatement system including a burn section and a wet section or a plasma-wet abatement system.

13. The system of claim 12, wherein, when the first pre-pump plasma abatement reactor is circumvented, the post-pump abatement reactor is activated to replace the first pre-pump plasma abatement reactor.

14. The system of claim 12, wherein, when the first pre-pump plasma abatement reactor is circumvented, the post-pump abatement reactor is activated to complement the first pre-pump plasma abatement reactor.

15. The system of claim 12, wherein, when the first pre-pump plasma abatement reactor is circumvented, the burn section of the post-pump abatement reactor is activated to receive gases rerouted from the first pre-pump plasma abatement reactor.

16. A method, comprising:
coupling, by a first pre-reactor foreline, a first processing chamber to a first pre-pump plasma abatement reactor, the first pre-pump plasma abatement reactor coupled by a first post-reactor foreline to a first pump; and
selectively coupling, by a backup pre-pump plasma abatement reactor, the first processing chamber to the first pump in a manner that prevents gases from being abated by the first pre-pump plasma abatement reactor.

17. The method of claim 16, further comprising:
coupling, by a second pre-reactor foreline, a second processing chamber to a second pre-pump plasma abatement reactor, the second pre-pump plasma abatement reactor coupled by a second post-reactor foreline to a second pump, wherein the backup pre-pump plasma abatement reactor is configured to selectively couple the second processing chamber to the second pump in a manner that circumvents the second pre-pump plasma abatement reactor.

18. The method of claim 17, further comprising:
connecting a post-pump abatement system to outlets of the first and second pumps.

19. The method of claim 16, wherein one or more first valves having states control through which of the first pre-pump plasma abatement reactor and the backup pre-pump plasma abatement reactor the first processing chamber is connected to the first pump.

20. The method of claim 19, wherein an abatement reagent delivery system is coupled to the first pre-reactor foreline between the one or more first valves and the first processing chamber.
